(19) United States
(12) Patent Application Publication
(10) Pub. No.: US 2026/0231593 A1
(43) Pub. Date: Aug. 6, 2026

(54) STABILIZATION OF LEAD IODIDE PEROVSKITE-BASED DEVICES

(71) Applicant: The Trustees of Princeton University, Princeton, NJ (US)

(72) Inventors: Barry RAND, Princeton, NJ (US); Jeffrey SCHEARTZ, Princeton, NJ (US); Junnan HU, Princeton, NJ (US)

(73) Assignee: The Trustees of Princeton University, Princeton, NJ (US)

(21) Appl. No.: 19/476,848

(22) PCT Filed: Apr. 19, 2024
(86) PCT No.: PCT/US2024/025412

§ 371 Date: Oct. 20, 2025

Related U.S. Application Data
(60) Provisional application No. 63/460,669, filed on Apr. 20, 2023.

(51) Int. Cl. H10K 30/40

(52) U.S. Cl. CPC H10K 30/40

(57) ABSTRACT

Perovskite-based devices are susceptible to degradation that stems from formation of oxidized iodine species which simultaneously facilitates degradation of both perovskite and hole transport layers. Improved devices are provided that utilized a halide perovskite layer disposed between a first electrode and a second electrode, where either the halide perovskite layer is adjacent to a reducing agent; and/or at least one intermediate layer comprising the reducing agent is between the halide perovskite layer and the first electrode, the second electrode, or both.

### CROSS-REFERENCE TO RELATED APPLICATIONS

The present application claims priority to U.S. Provisional Patent Application No. 63/460,669, filed Apr. 20, 2023, the contents of which are incorporated by reference herein in its entirety.

### STATEMENT REGARDING FEDERALLY SPONSORED RESEARCH OR DEVELOPMENT

This invention was made with government support under Grant No. DE-EE0008560 awarded by the Department of Energy. The government has certain rights in the invention.

### TECHNICAL FIELD

The present disclosure is drawn to perovskite devices, and specifically lead iodide perovskite-based devices.

### BACKGROUND

Perovskite-based devices, such as perovskite solar cells (PSCs), have shown impressive performance; however, they are susceptible to degradation that stems from formation of iodine species which simultaneously facilitates degradation of both perovskite and hole transport layers. In formamidinium (FA) lead iodide perovskite, degradation is determined to be a self-propagating process involving oxidized forms of iodide (e.g., I⁰, I₂, triiodide (I₃⁻), I₇⁻, etc.); I₃⁻ is found capable of deprotonating FA; in the hole transport layer, infiltration of iodine species interrupts hole transport. While previously-reported physical iodine barriers might block oxidized iodine-containing species from entering the hole transport layer, it also confines the oxidized iodine to that interface and perovskite degradation is accelerated.

### BRIEF SUMMARY

In various aspects, a halide perovskite-based device (such as an organic cation lead iodide perovskite-based device) may be provided. The device may include a first electrode and a second electrode. The device may include a halide perovskite layer disposed between the first electrode and the second electrode. At least one intermediate layer may be between the halide perovskite layer and the first electrode, the second electrode, or both, where the at least one intermediate layer may include a reducing agent. The reducing agent may include a thiol. The thiol may be, e.g., an alkylthiol, arylthiol, or heterocyclic thiol. In a preferred embodiment, the reducing agent is 5-methoxy-2-benzimidazolethiol (2BI-OMe).

The at least one intermediate layer may be adjacent to the halide perovskite layer. The device may include a first transport layer between the halide perovskite layer and the first electrode. The first transport layer may be disposed between the at least one intermediate layer and the first electrode. The device may include a second transport layer between the halide perovskite layer and the second electrode. The second transport layer may be disposed between the at least one intermediate layer and the second electrode.

In various aspects, a method for stabilizing performance of a halide perovskite device may be provided. The method may include incorporating a reducing agent into a halide perovskite device (while the device is being manufactured), by depositing the reducing agent into a layer above or below a layer comprising a halide perovskite. The reducing agent may be a thiol. The thiol may be 5-methoxy-2-benzimidazolethiol.

Depositing the reducing agent may include forming a transport layer that incorporates the reducing agent. Depositing the reducing agent may include forming a reducing agent layer between an electrode and a transport layer. Depositing the reducing agent may include forming a reducing agent layer adjacent to the layer comprising the halide perovskite.

### BRIEF DESCRIPTION OF DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1A is a schematic representation of the catalytic effect of I₂ on the decomposition of methylammonium (MA⁺) or formamidinium (FA⁺).

FIG. 1B is a schematic representation of the interruption of the catalytic cycle via reduction of I₂ to iodide by 2BI-OMe.

FIGS. 2 and 3 are illustrations of embodiments of a perovskite-based device.

FIGS. 4A and 4B are cross-sectional STEM-EDX measurements at the Spiro-FAPbI₃ (spiro-OMeTAD or Spiro is 2,2′,7,7′-tetrakis[N,N-di(4-methoxyphenyl)amino]-9-9′-spirobifluorene) interface of a perovskite solar cell construct after heating to 85° C., where the Spiro-FAPbI₃ interface without 2BI-OMe (4A) showing I₂ intrusion into Spiro (see arrow at ref. 400); and the Spiro-FAPbI₃ interface with 2BI-OMe inserted at the interface (4A) showing I₂ intrusion is almost undetected.

FIG. 4C is a graph showing conductivity vs time for Spiro/Au and variously treated FAPbI₃/thiol/Spiro/Au samples at 85° C.

FIG. 5A is a graph showing Forward scan (FS) and reverse scan (RS) current density-voltage (J-V) curves of PSCs with and without 2BI-OMe at the FAPbI₃/Spiro interface; the inset includes the steady-state power output (SPO) efficiency with applied voltage (Vₐₚₚ) at the maximum power point.

FIG. 5B is a boxplot showing PCE (solid lines) and V_{OC} (dotted lines) distributions for 12 PSC devices surface-treated variously (center line, median; box, 25-75% standard deviation; “whiskers”, outliers).

FIG. 5C shows UPS spectra of FAPbI₃ perovskites with various surface treatments highlighting work function changes.

FIG. 5D shows illustrations of thiols on the perovskite surface, and attendant relative, qualitative dipole moments, and measured work function data.

FIG. 6 is a set of graphs showing PSC performance (PCE; J_{SC}; FF) versus heating at 85° C. in N₂ over 300 h. Twelve devices were monitored for each group; devices were cooled to room temperature before measurement.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION

The following description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for illustrative purposes to aid the reader in understanding the principles of the invention and the concepts contributed by the inventor(s) to furthering the art and are to be construed as being without limitation to such specifically recited examples and conditions. Additionally, the term, “or,” as used herein, refers to a non-exclusive or, unless otherwise indicated (e.g., “or else” or “or in the alternative”). Also, the various embodiments described herein are not necessarily mutually exclusive, as some embodiments can be combined with one or more other embodiments to form new embodiments.

The numerous innovative teachings of the present application will be described with particular reference to the presently preferred exemplary embodiments. However, it should be understood that this class of embodiments provides only a few examples of the many advantageous uses of the innovative teachings herein. In general, statements made in the specification of the present application do not necessarily limit any of the various claimed inventions. Moreover, some statements may apply to some inventive features but not to others. Those skilled in the art and informed by the teachings herein will realize that the invention is also applicable to various other technical areas or embodiments.

Improvements in power conversion efficiency (PCE) of lead iodide-based perovskite solar cells (PSCs) command attention, yet limits on their thermal stability can still adversely impact device lifetimes compared with other solar technologies. Device operating temperatures can reach 70° C., and CsₓFA₁₋ₓPbI₃ (FA⁺, formamidinium) perovskites that are considered to be thermally “stable” slowly release byproducts indicative of thermal degradation.

Noteworthy among these products, oxidized iodine-containing species (e.g., I₀, I₂⁻, I₃⁻, I₇⁻, I₉⁻, etc.) are clearly problematic: indeed, metal etching and corrosion by I₂/I is well-known, and oxidation can compromise the function of hole-transport layer (HTL) materials such as p-doped Spiro-OMeTAD (“Spiro”) that otherwise benefits from its high hole extracting ability and ease of deposition via solution processing. A subtle, yet powerful role that these oxidized iodine-containing species play on catalyzing degradation of FA⁺ or methylammonium (MA⁺) perovskites has been demonstrated; no particular, molecular role for either I₂ and I₃⁻ had been identified.

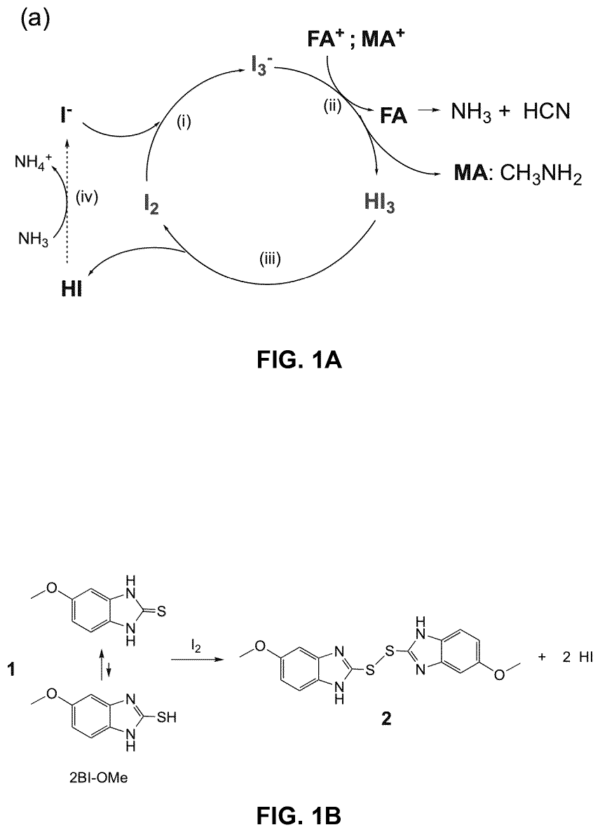

Based on nuclear magnetic resonance (NMR) analysis, it is disclosed herein that I₃⁻ hydrogen-bonds unexpectedly and strongly with MA⁺ or FA⁺; I⁻ alone does not hydrogen-bond with either MA⁺ or FA⁺. Deprotonation of MA⁺ or FA⁺ then ensues, leading to methylamine or formamidine, respectively; the latter decomposes rapidly. Furthermore, I₂ is regenerated in this overall process and, therefore, can participate in a catalytic cycle for overall decomposition of MA⁺ or FA⁺ perovskite materials. This is shown schematically in FIG. 1A, where initially, thermal treatment of the perovskite yields I₂ and Pb⁰: i) I₂ reacts with iodide to give triiodide, I₃⁻; ii) I₃⁻ hydrogen-bonds with MA⁺ or FA⁺ leading to their deprotonation; methylamine can simply volatilize or reprotonate, but formamidine rapidly decomposes to HCN and NH₃; iii) HI₃ is in equilibrium with HI and I₂, which completes the catalytic cycle. iv) In a side reaction, HI reacts with NH₃ from formamidine decomposition to give ammonium iodide.

It is also disclosed herein that a simple thiol applied to the perovskite surface at its interface with Spiro reductively intercepts thermally formed iodine species and prevents their intrusion into the HTL. This is shown in FIG. 1B, where interruption of the catalytic cycle is accomplished by reduction of I₂ to iodide by 2BI-OMe (1). Bis(5-methoxy-1H-benzimidazol)disulfide (2) is also formed. The disclosed treatment obviates thiol incorporation into the perovskite bulk, yet it still minimizes triiodide-catalyzed perovskite thermal degradation. As a bonus, as shown by ultraviolet photoelectron spectroscopy (UPS), thiols used in the disclosed surface treatment systematically affect the work function of their perovskite ensembles, and thus facilitate hole injection into Spiro.

While the above relates to oxidized iodine species reduction, the disclosed thiol treatment may be applied to any halide perovskite device to avoid halide oxidation, a key degradation pathway.

In various aspects, a halide perovskite-based device, such as an iodide perovskite-based device, such as an organic cation lead iodide perovskite-based device, may be provided.

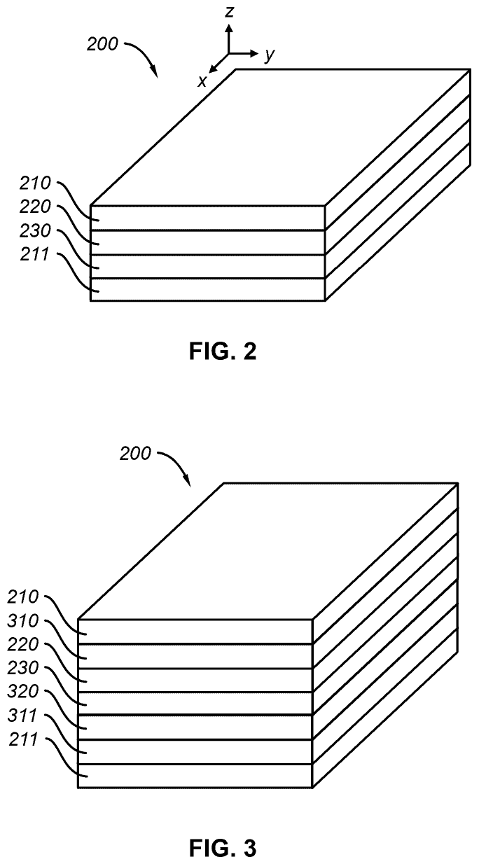

Referring to FIG. 2, the device (200) may include a first electrode (210) and a second electrode (211).

Each electrode may be independently composed of any appropriate material, and may be composed of the same material(s), or may be composed of different material(s). In some embodiment, an electrode may include a transparent or semi-transparent electrically conductive material. In some embodiments, the electrode may include a layer of a transparent conducting oxide or a metal. Non-limiting examples of transparent conducting oxides include tin oxide, zinc oxide, doped tin oxide and doped zinc oxide. For instance, a transparent conducting oxide may include Indium Tin Oxide (ITO), Indium Cerium Oxide (ICO), Indium Tungsten Oxide (IWO), fluorine-doped tin oxide (FTO) or aluminum zinc oxide (AZO). In some embodiments, The electrode may include a metal, such as silver (Ag), aluminum (Al), gold (Au), copper (Cu), platinum (Pt), or palladium (Pd).

The electrode material may have a thickness (e.g., in the z or out-of-plane direction) of from 1 to 200 nm, from 1 to 100 nm, from 2 to 50 nm, or from 2 to 25 nm.

The device may include a halide perovskite layer (230) disposed between the first electrode and the second electrode. Any appropriate halide perovskite material may be utilized. In preferred embodiments, the halide perovskite material is an organometallic perovskite material. In an embodiment, the organometallic halide structure can have the following formula: AMX₃. In an embodiment, A can be an organic cation such as alkyl-ammonium (e.g., methylammonium), formamidinium, or an inorganic cation such Cesium (Cs), or a combination thereof. In some embodiments, the alkyl-ammonium cation may include an alkyl portion that is a linear or branched hydrocarbon moiety, and preferably the alkyl portion may include one to six carbon atoms. In a particular embodiment, A is FA or MA. In an embodiment, M can be a cation or divalent cation of an element such as Pb, Sn, Cu, Ni, Co, Fe, Mn, Pd, Cd, Ge, Cs, or Eu. In a particular embodiment, M is Pb. In an embodiment, X can be a halide anion such as Cl, Br, F, I, and At. In particular, X may be I. The selection of the components of AMX₃ may be made so that the organometallic halide has a neutral charge.

The device may include at least one intermediate layer (220), each of which may be between the halide perovskite layer and the first electrode, the second electrode, or both. Each intermediate layer may be a hole transport layer or a charge transport layer, or may be separate from such a transport layer. The at least one intermediate layer may include a reducing agent. The reducing agent may include a thiol. Non-limiting examples of acceptable thiols include alkylthiols, alkenylthiols, alkylenethiols, arylthiols, heterocyclic thiols, fused ring aryl thiols, fused ring heterocyclic thiols, alkoxythiols, etc.

As shown in FIG. 1B, the protons associated with the oxidized thiol-SH group are removed, allowing two thiyl groups to bond together, while the two protons that were removed each bond with a halide ion. One skilled in the art will readily appreciate this reaction as it applies to various thiols, and that alternative example embodiments of the structures and methods disclosed herein may be employed without departing from the principles described herein.

Any thiol will be able to perform this function. It is believed the molecular size and oxidation of the thiol relate to the performance of the thiol in these devices.

In some embodiments, the thiol may be a substituted or unsubstituted alkyl thiol. The thiol may be a cyclic thiol compound. The thiol may have a structure according to formula (I):

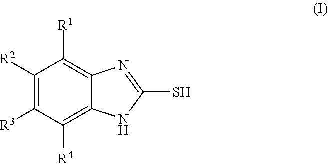

where each of R¹, R², R³, and R⁴ are independently an alkyl group, an alkenyl group, an alkoxy group, an alkoxycarbonyl group, an alkylene group, an alkylidene group, a cycloalkyl group, a halogen, or a hydrogen. In a preferred embodiment, at least one of R¹, R², R³, and R⁴ is an alkyl or alkoxy group. In a more preferred embodiment, only one of R¹, R², R³, and R⁴ is an alkoxy group.

In a more preferred embodiment, the reducing agent may be 5-methoxy-2-benzimidazolethiol (2BI-OMe):

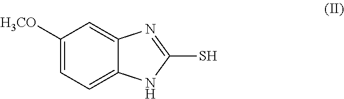 [SMILES: COc1ccc2[nH]c(S)nc2c1]

As used herein, the term “alkyl” refers to a straight or branched chain C₁₋₁₀ alkyl group, for example, methyl, ethyl, n-propyl, isopropyl, n-butyl, isobutyl, sec-butyl, tert-butyl, pentyl, hexyl, heptyl, octyl or the like. As used herein, the term “alkenyl” refers to a straight or branched chain C₂₋₁₀ alkenyl group, for example, vinyl, allyl, isopropenyl, butenyl, pentenyl, hexenyl, heptenyl, octenyl or the like. As used herein, the term “alkoxy” refers to a straight or branched chain C₁₋₁₀ alkoxy group, for example, methoxy, ethoxy, n-propoxy, isopropoxy, n-butoxy, isobutoxy, sec-butoxy, tert-butoxy, pentyloxy, hexyloxy, heptyloxy, octyloxy or the like. As used herein, the term “alkoxycarbonyl” refers to an alkoxy-CO— group (in which the alkoxy represents the above-mentioned straight or branched chain C₁₋₁₀ alkoxy group), for example, methoxy-carbonyl, ethoxycarbonyl, n-propoxycarbonyl, isopropoxy-carbonyl, n-butoxycarbonyl, isobutoxycarbonyl, sec-butoxycarbonyl, tert-butoxycarbonyl, pentyloxycarbonyl or the like. As used herein, the term “alkylene” refers to a straight or branched chain C₁₋₁₀ alkylene group, for example, ethylene, trimethylene, tetramethylene, 1,2-dimethylethylene, 1,3-dimethyl-trimethylene, 1,1,2,2-tetramethylethylene or the like. As used herein, the term “alkylidene” refers to a straight or branched chain C₁₋₁₀ alkylidene group, for example, methylene, ethylidene, propylidene, isopropylidene, butylidene, hexylidene, octylidene or the like. As used herein, the term “cycloalkyl” refers to a C₃₋₆ cycloalkyl group, for example, cyclopropyl, cyclobutyl, cyclopentyl, cyclohexyl or the like.

As shown in FIG. 2, an intermediate layer (220) may be directly adjacent to (i.e., in contact with) the perovskite layer (230).

In some embodiments, the intermediate layer may consist of the reducing agent. In some embodiments, the intermediate layer may consist of the reducing agent and an inert material (e.g., a material that does not interact with surrounding layers, such as a polymeric material intended only to provide additional structure). In some embodiments, the intermediate layer may form a transport layer, such as an electron transport layer. In such cases, the electron transport layer may comprise the reducing agent.

Referring to FIG. 3, in some embodiments, the device may include a first transport layer (310) between the halide perovskite layer (230) and the first electrode (210). The first transport layer (310) may be disposed between an intermediate layer (here, a first intermediate layer, shown as intermediate layer (220)) and the first electrode (210). The device may include a second transport layer (311) between the halide perovskite layer (230) and the second electrode (211). The second transport layer (311) may be disposed between an intermediate layer (here, a second intermediate layer, shown as intermediate layer (320)) and the second electrode (211).

At least one transport layer may be a hole transport layer (HTL). The hole transport layer may include any appropriate hole transport material. Non-limiting examples of hole transport materials include 2,2′,7,7′-tetrakis[N,N-di(4-methoxyphenyl)amino]-9-9′-spirobifluorene (spiro-OMeTAD or Spiro), m-MTDATA, TDATA, 2-TNATA, NPB, β-NPB, TPD, Spiro-TPD, Spiro-NPB, methylated-NPB, TAPC, HMTPD, 4,4′,4″-tris(N-polyaniline/dodecylbenzenesulfonic carbazolyl)triphenylamine (TCTA), acid: polyaniline/dodecylbenzene sulfonic acid (Pani/DBSA), poly(3,4-ethylene dioxythiophene)/poly(4-styrene sulfonate (PEDOT/PSS), polyaniline/camphor sulfonic acid: polyaniline (Pani/CSA), and polyaniline/poly(4-styrene sulfonate) (PANI/PSS).

At least one transport layer may be an electron transport layer (ETL). The electron transport layer may include any appropriate electron transport material. In some embodiments, the electron transport layer may include one or more metal oxides. Non-limiting examples include zinc oxide, tin oxide, titanium oxide, aluminum oxide, niobium oxide, yttrium oxide, and barium titanate. In some embodiments, the electron transport layer may include one or more organic compounds. Non-limiting examples include of 1,3,5-tris(N-phenylbenzimidazol-2-yl)benzene (TPBI) or 3-(4-biphenyl)-4-phenyl-5-t-butylphenyl-1,2,4-triazole (TAZ).

In various aspects, a method for stabilizing performance of a halide perovskite device may be provided. The method may include incorporating a reducing agent as disclosed herein into a halide perovskite device, by depositing the reducing agent into a layer above or below a layer comprising a halide perovskite. Depositing the reducing agent may include forming a reducing agent layer between an electrode and a transport layer. Depositing the reducing agent may include forming a reducing agent layer adjacent to the layer comprising the halide perovskite.

### Surface and Perovskite Spiro Interfacial Thiol Treatment of Thin Films

Since I₂ exposure can cause degradation of solid MAPbI₃ or FAPbI₃, the disclosed approach can be used to minimize its deleterious effects. It was found that simply treating preformed, solid FAPbI₃ film surfaces with a thiol (one particular example used 5-methoxy-12-benzimidazolethiol (2BI-OMe)) suppressed dramatically degradation by I₂-exposure. As can be confirmed by X-ray photoelectron spectroscopy (XPS) depth studies, this surface treatment does not lead to thiol penetration into the bulk perovskite.

Results of exposure to I₂ vapor of FAPbI₃ that was untreated was compared to FAPbI₃ that was surface-treated with 2BI-OMe. As can be seen in X-ray diffraction (XRD) patterns, the increase in PbI₂ formation (and also light-inactive 8-FAPbI₃) that correlates with increased I₂ exposure for untreated FAPbI₃ was suppressed by the disclosed surface treatment approach.

Thermal stress causes degradation of MAPbI₃ to include PbI₂ and I₂; FAPbI₃ behaves similarly. As a control here, FAPbI₃ was heated at 85° C. under N₂ for 1 week, and PbI₂ was observed by XRD; thin films of FAPbI₃ immersed in toluene and heated at 85° C. even for only 1 h under N₂ produced I₂ as determined by the peak at ca. 500 nm in the UV-vis spectrum of the supernatant. In contrast, adding 2BI-OMe (FIG. 1B, species 1) to the FAPbI₃ film surface resulted in the near complete elimination of PbI₂ under this thermal stress; no I₂ was observed by UV-vis analysis of supernatant liquid when the 2BI-OMe-treated FAPbI₃ film was heated in toluene.

Using Spiro as the hole-transport material in PSCs necessitates its contact with the perovskite. Therefore, in this example, Spiro was spin-coated onto FAPbI₃ and then the ensemble was thermally stressed to test the effect of such coating on the chemistry both of Spiro and of the perovskite. Spiro spin-coated FAPbI₃ was heated to 85° C. for 1 week and was then washed with chlorobenzene to re-expose the FAPbI₃ surface for characterization. Spiro spin-coated FAPbI₃ showed a larger relative amount of degradation product PbI₂ than did similarly stressed, uncoated FAPbI₃. A cover-layer of Spiro could suppress volatile I₂ from escape into the ambient, so its presence could lead to increased FAPbI₃ degradation (see FIG. 1A). To test this “capping” proposal, poly(methyl methacrylate) (PMMA) was coated on FAPbI₃; as expected, degradation products PbI₂ increased and 8-FAPbI₃ could be observed relative to those with Spiro coating: as with Spiro, the PMMA layer could suppress escape of volatile I₂, but unlike Spiro, diffusion of oxidized iodine species into PMMA does not occur, making PMMA a better barrier overall. Nonetheless, even here a layer of 2BI-OMe inserted between the perovskite and PMMA suppressed formation of FAPbI₃ degradation products. The effect of the 2BI-OMe interlayer on thermally stressed Spiro- or PMMA-coated FAPbI₃ was assayed using XPS. No discernible change was observed in the Pb 4f spectra of clean or Spiro-coated FAPbI₃; however, new peaks appeared near 137 and 142 eV that are attributed to Pb⁰ derived from thermal degradation of PMMA-capped FAPbI₃. It is significant that no Pb⁰ was observed for heated FAPbI_{3/2}BI-OMe/PMMA, suggesting that the disulfide corollary product of I₂ reduction (e.g., FIG. 1B, species 2) can oxidize Pb⁰ back to Pb^{II}; a “redox recycle” of Pb⁰ and I₂ back to PbI₂ thus exists commensurately with thiol oxidation-disulfide reduction at the FAPbI₃ surface.

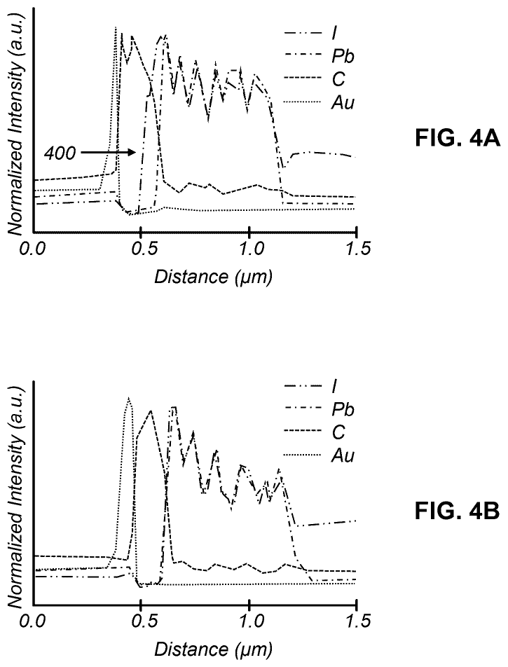

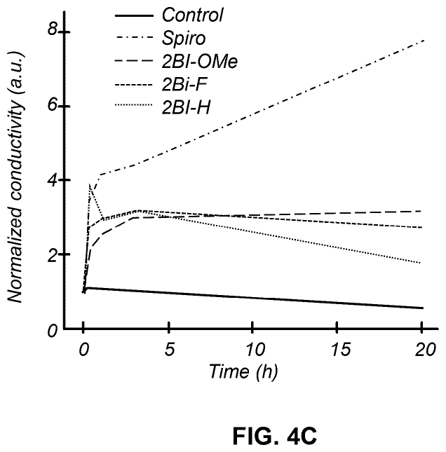

Migration of thermally produced I₂ or I₃⁻ into Spiro can lead to contact corrosion and could also increase Spiro p-doping, deviating the ratio Spiro:“Spiro⁺” from its optimal range. To address this latter issue and its possible remediation, the effect of 2BI-OMe deposited at the Spiro-FAPbI₃ interface on migration of iodine species into Spiro was investigated in model PSC n-i-p devices, FTO/SnO₂/FAPbI₃/Spiro/Au and FTO/SnO₂/FAPbI_{3/2}BI-OMe/Spiro/Au, that were stressed at 85° C. for 300 h. Energy-dispersive X-ray (EDX) spectroscopy line scans for the device without 2BI-OMe showed significant iodine penetration into Spiro to a depth of ca. 80 nm (see FIG. 4A, and ref. 400 arrow indicating the penetration). In marked contrast, minimal iodine migration into Spiro occurred for the device where the 2BI-OMe layer was inserted at the perovskite/Spiro interface (see FIG. 4B); surface treatment with the thiol thus yields an I₂-reducing interface.

Next, Spiro-based conductivity in contact with FAPbI₃ was measured as a function of annealing time at 85° C. (see FIG. 4C). In this way the effect of intrusion of I₂ species into the Spiro could be related directly to device function. Note that the conductivity of the Spiro-only sample (Spiro/Au; dot-dashed line) increases throughout annealing; the presence of the perovskite underlayer in a second control sample (FAPbI₃/Spiro/Au; solid line) compromises this trend. These data are consistent with previous reports that conductivity decline is attributed to iodine infiltration into Spiro. The inclusion of any of three thiol analogs 5-methoxy-2-benzimidazolethiol (2BI-OMe), 2-benzimidazolethiol (2BI-H) or 5-fluorine-2-benzimidazolethiol (2BI-F), leads to intermediate trends, likely due to ability of each under thermal stress to intercept I₂ at the FAPbI₃-Spiro interface I₂; 2BI-OMe was the best of the three for mitigating ultimately a decline in Spiro conductivity, although all of the thiols mitigated to some degree.

### Interfacial Thiol Treatment and Performance of PSCs

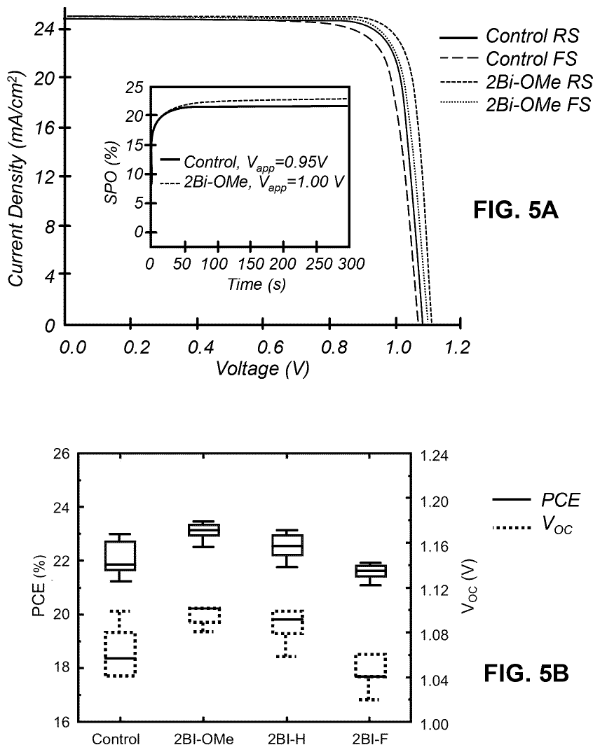

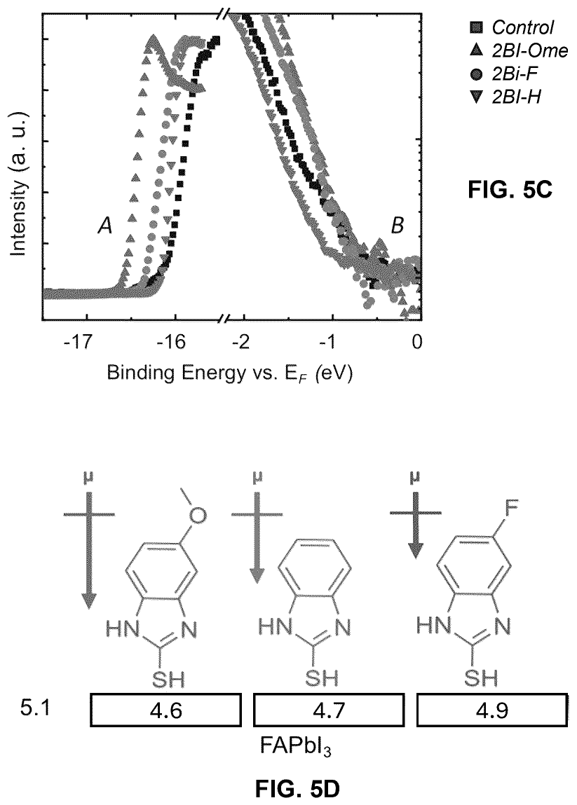

Introducing interfacial 2BI-OMe improved the overall performance of FAPbI₃/Spiro-based PSCs: current density vs voltage (J-V) curves of high-performance PSCs were compared with or without interfacial 2BI-OMe, as was their stabilized output operating at the maximum power point (FIG. 5A). Both series showed similar hysteresis. Parallel trends for measured PCE and open circuit voltages (V_{OC}) for the untreated and variously thiol-treated devices was also noted; 2BI-OMe treated devices were better by both metrics with a “champion” PCE of 23.5% (reverse scan) that was higher than that for the untreated controls (22.9%); average values for PCE (V_{OC}) were 23.04% (1.10 V) for treated devices, and 22.06% (1.06 V) for controls (FIG. 5B).

To further the analysis of the role played by the thiols in these devices, UPS was measured for FAPbI₃ (FIG. 5C) as a function of surface treatment. Data were analyzed after careful He(I) satellite subtraction to determine Fermi level and valence band maximum (VBM) positions; the work function for each sample was obtained from its photoemission cut-off (FIG. 5C, Region A). The work function of untreated FAPbI₃ is 5.1 eV; adding any of the interfacial thiols lowers this value, to 4.6 eV with 2BI-OMe, 4.7 eV with 2BI-H and 4.9 eV with 2BI-F. These changes are likely due to dipoles introduced at the FAPbI₃ surface by these thiol species that combine the molecular dipole moment of each isolated species with the “anchor dipole” from the interaction of the —SH group and the perovskite surface (FIG. 5D). Note that a shift of the Fermi level relative to the VBM of the untreated perovskite could also change the work function, but this cannot be assessed from UPS data in FIG. 5C given that the top of the perovskite valence band is masked by emission from the thiol layer. In the present case, the apparent shifts of the filled states relative to the Fermi level (FIG. 5C, Region B) are likely due to different densities of states of the various thiol molecules rather than to an effective shift of the Fermi level relative to the perovskite VBM. Of the three thiols, interfacial treatment with 2BI-OMe resulted in the greatest decrease in FAPbI₃ work function, which supports the analysis of V_{OC} and PCE (FIG. 5B) data for the FAPbI₃/thiol/Spiro devices tested. Device results are interpreted to derive from a realignment of the Spiro molecular levels relative to the FAPbI₃ valence levels. The electronic structure of the MAPbI₃-Spiro interface, which is believed to hold as well for the FAPbI₃-Spiro interface, obeys vacuum level alignment, meaning that the energy difference between the perovskite VBM and the Spiro highest occupied molecular orbital (HOMO) is simply the difference between the ionization energies of the two materials. The lowering of the perovskite work function by the thiol molecule-induced dipole lowers the vacuum level of the former, and leads to a realignment of energy levels, as previously observed at numerous interfaces involving organic thin films. In the present case, the lowering of the perovskite vacuum levels leads to a decrease in the energy difference between its VBM and the Spiro HOMO, still allowing for efficient hole extraction, but also slightly increasing the “solar cell gap” and, therefore, V_{OC}.

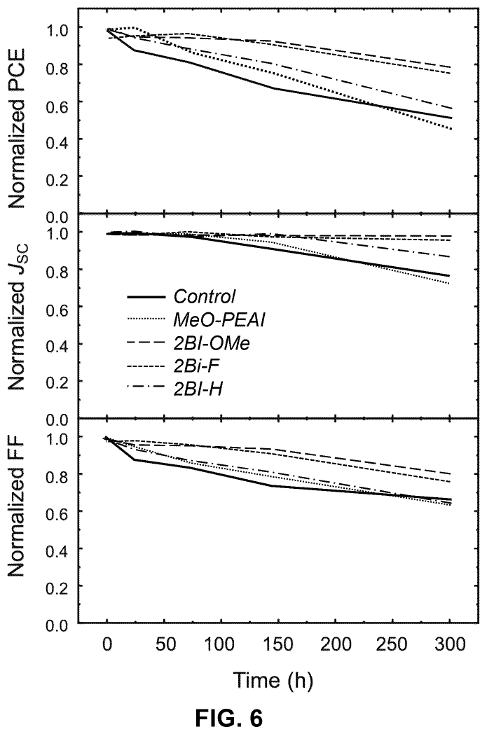

The spectroscopy measurements are related to stability by comparing performance under thermal stress at 85° C. of PSC devices that are based on FAPbI₃/Spiro versus FAPbI₃/thiol/Spiro architectures. The three thiols were incorporated individually in 12 devices, as was 4-methoxy-phenethylammonium iodide (MeO-PEAI) that is used in 3D/2D PSC architecture to improve PCE; MeO-PEAI served as a second control. The PCE of the untreated control device dropped significantly on heating (FIG. 6) as reported elsewhere. The PCEs of devices with MeO-PEAI or 2BI-H interlayers were maintained for 24 h, but then dropped rapidly. In significant contrast, the PCEs of devices using 2BI-MeO or 2BI-F interlayers dropped slowly over time and maintained over 80% of their initial PCE after 300 h (FIG. 5A). Values of J_{SC}, FF, and V_{OC} for 2BI-MeO- or 2BI-F-incorporated PSCs were also measured versus time. It was found that the decline in FF over the first 150 h of study accompanies the PCE drop. Analysis of J-V curves at several heating times suggests a significant increase occurs in series resistance, especially for control FAPbI₃/Spiro- and FAPbI₃/MeO-PEAI/Spiro-based devices, suggesting deterioration of Spiro or Spiro/perovskite interfaces that are due to I₂ intrusion (see FIG. 4A). At longer times the decrease of J_{SC} begins to contribute to PCE drop as could formation of voids at the interface that decrease its effective contact area: interfacial contact between the Spiro and perovskite layers was imaged by high-angle annular dark-field cross-sectional scanning transmission electron microscopy, and void at the interface were far more prevalent in the control devices than in the FAPbI₃/thiol/Spiro-based devices. The overall change in V_{OC} is small. Clearly, PSC devices incorporating FAPbI₃/thiol/Spiro constructs generally outperform those based on FAPbI₃/Spiro or FAPbI₃/MeO-PEAI/Spiro ones in thermal stability. Differences within the thiol family are noteworthy: apart from their unique dipole moments, thermogravimetric analysis (TGA) shows the thiols can volatilize differentially under the 85° C. conditions of these tests, which was confirmed by XPS; S 2p was observed only for FAPbI_{3/2}BI-OMe after prolonged heating.

### Device Fabrication

To prepare the SnO₂ electron-transport layer, 140 mg SnCl₂·2H₂O and 625 mg urea were dissolved in 50 mL of deionized water containing thioglycolic acid (12.5 μL) and HCl (625 μL). Fluorine tin oxide (FTO)-coated glass substrates (Asahi FTO glass, 12-13 (2 cm-2) were immersed in this aqueous solution for 6-7 h; they were then removed from solution and were annealed for 0.5 h at 150° C. The glass substrate was spin-coated at 5000 rpm for 30 s with 100 μL of KCl in H₂O (35 mg in 7 mL), and were then annealed 150° C. for 15 min. Perovskite precursor solutions (1.4 m FAPbI₃) were prepared in an N₂-atmosphere glovebox and consisted of FAI:PbI₂:MACl:MDACl₂ in 1:1:0.35:0.04 molar ratios in DMF: DMSO (800 μL: 100 μL). Perovskite precursor solutions (60 μL) were spin-coated onto FTO-coated glass substrates sequentially at 400 rpm for 4 s, 900 rpm for 4 s, and then 5000 rpm for 20 s; 1 mL of ethyl ether was dripped onto the substrate 11 s after spin-coating had reached 5000 rpm. The perovskite product thus formed was annealed at 120° C. for 40 min.

Treatment of Perovskites with Thiols

The perovskite films prepared on FTO-coated glass were spin-coated at 5000 rpm with 100 μL of the thiol solution (3 mg in 1 mL IPA), or with 100 μL of MeO-PEAI solution (4 mg in 1 mL IPA); each was then annealed at 100° C. for 5 min. Thiol-treated perovskite films were stored overnight in vacuo. Spiro-OMeTAD (94 mg) was dissolved in 1.1 mL chlorobenzene containing 37 μL of tert-butylpyridine, 23 μL of a solution of Li-TFSI salt prepared from 520 mg in 1 mL acetonitrile, and 10 μL of Co-TFSI salt prepared from 375 mg in 1 mL in acetonitrile. The resulting solution (60 μL) was spin-coated at 3500 rpm on the perovskite films for 30 s; there was no subsequent annealing. Finally, a 70 nm thick gold counter electrode was deposited on the Spiro-perovskite ensemble by thermal evaporation.

Various modifications may be made to the systems, methods, apparatus, mechanisms, techniques, and portions thereof described herein with respect to the various figures, such modifications being contemplated as being within the scope of the invention. For example, while a specific order of steps or arrangement of functional elements is presented in the various embodiments described herein, various other orders/arrangements of steps or functional elements may be utilized within the context of the various embodiments. Further, while modifications to embodiments may be discussed individually, various embodiments may use multiple modifications contemporaneously or in sequence, compound modifications and the like.

Although various embodiments which incorporate the teachings of the present invention have been shown and described in detail herein, those skilled in the art can readily devise many other varied embodiments that still incorporate these teachings. Thus, while the foregoing is directed to various embodiments of the present invention, other and further embodiments of the invention may be devised without departing from the basic scope thereof. As such, the appropriate scope of the invention is to be determined according to the claims.

1. A halide perovskite-based device, comprising:
a first electrode and a second electrode;
a halide perovskite layer disposed between the first electrode and the second electrode;
a hole transport layer between the halide perovskite layer and the second electrode; and
at least one intermediate layer comprising a reducing agent, the at least one intermediate layer including a first intermediate layer between the halide perovskite layer and the hole transport layer.

2. The halide perovskite-based device according to claim 1, further comprising a first transport layer between the halide perovskite layer and the first electrode.

3. The halide perovskite-based device according to claim 2, wherein the first transport layer is disposed between the at least one intermediate layer and the first electrode.

4. The halide perovskite-based device according to claim 2, further comprising a second transport layer between the halide perovskite layer and the second electrode.

5. The halide perovskite-based device according to claim 4, wherein the second transport layer is disposed between the at least one intermediate layer and the second electrode.

6. The halide perovskite-based device according to claim 1, wherein the reducing agent comprises a thiol.

7. The halide perovskite-based device according to claim 6, wherein the thiol is an alkylthiol, an arylthiol, a heterocyclic thiol, a fused ring arylthiol, or a fused ring heterocyclic thiol.

8. The halide perovskite-based device according to claim 7, wherein the thiol is 5-methoxy-2-benzimidazolethiol.

9. The halide perovskite-based device according to claim 6, wherein the at least one intermediate layer is adjacent to the halide perovskite layer.

10. The halide perovskite-based device according to claim 9, wherein the at least one intermediate layer consists of the reducing agent.

11. The halide perovskite-based device according to claim 1, wherein the at least one intermediate layer forms an electron transport layer that incorporates the reducing agent.

12. The halide perovskite-based device according to claim 1, wherein the halide perovskite-based device is an organic cation lead iodide perovskite-based device.

13. A method for stabilizing performance of a halide perovskite device, comprising:
incorporating a reducing agent into a halide perovskite device, by depositing an intermediate layer between a layer comprising a halide perovskite and a hole transport layer, the intermediate layer including the reducing agent.

14. The method according to claim 13, wherein the reducing agent comprises a thiol.

15. The method according to claim 14, wherein the thiol is 5-methoxy-2-benzimidazolethiol.

16. The method according to claim 13, wherein depositing the intermediate layer comprises forming an electron transport layer that incorporates the reducing agent.

17. The method according to claim 13, wherein depositing the intermediate layer comprises forming a reducing agent layer between an electrode and a transport layer.

18. The method according to claim 13, wherein depositing the intermediate layer comprises forming a reducing agent layer adjacent to the layer comprising the halide perovskite.

19. The halide perovskite-based device of claim 1, wherein the at least one intermediate layer consists of the first intermediate layer.

20. The halide perovskite-based device of claim 1, wherein the at least one intermediate layer consists of (i) the first intermediate layer, and (ii) a second intermediate layer between the halide perovskite layer and the first electrode.
